(19) United States
(12) Patent Application Publication
(10) Pub. No.: US 2014/0176239 A1
(43) Pub. Date: Jun. 26, 2014

(54) ADAPTIVE CONTROL MECHANISMS TO CONTROL INPUT AND OUTPUT COMMON-MODE VOLTAGES OF DIFFERENTIAL AMPLIFIER CIRCUITS

(71) Applicant: LSI CORPORATION, Milpitas, CA (US)

(72) Inventor: Abhishek Duggal, Cordova, TN (US)

(73) Assignee: LSI Corporation, Milpitas, CA (US)

(21) Appl. No.: 13/726,282

(22) Filed: Dec. 24, 2012

(51) Int. Cl. H03F 3/45

(52) U.S. Cl. CPC H03F 3/45071
USPC 330/260

(57) ABSTRACT

An amplifier circuit includes differential input nodes, a differential amplifier stage having differential input terminals and differential output terminals, and an input common-mode voltage adaptation circuit connected between the differential input nodes of the amplifier circuit and the differential input terminals of the differential amplifier stage. During an input common-mode adaptation phase, the input common-mode voltage adaptation circuit forces the differential input terminals of the differential amplifier stage to a common-mode voltage equal to an adaptive reference voltage, independent of a common-mode voltage applied to the differential input nodes of the amplifier circuit during the input common-mode adaptation phase. During a normal period of operation of the amplifier circuit, the input common-mode voltage adaptation circuit maintains the common-mode voltage at the differential input terminals of the differential amplifier stage equal to the adaptive reference voltage, independent of an input differential voltage applied during the normal period of operation.

### FIELD OF THE INVENTION

The field generally relates to differential amplifier circuits and, in particular, adaptive control mechanisms for controlling input and output common-mode voltages of differential amplifier circuits.

### BACKGROUND

In many analog and mixed-signal electronic systems, differential signaling is used to electrically transmit information using two complementary voltage signals that are transmitted on two paired wires, referred to as a differential pair. With this method, the information transmitted is represented by the difference between the two complementary voltage signals. In these systems, a differential amplifier is used to amplify two complementary voltages transmitted on a differential pair. A differential amplifier includes inverting and non-inverting input terminals connected to a differential pair, and amplifies a difference between input voltage signals applied to the inverting and non-inverting input terminals, while rejecting an input common-mode voltage level. An input common-mode voltage is defined as the average voltage at the inverting and non-inverting input terminals of the differential amplifier. To maintain high gain and linearity of differential amplifier circuits, it is desirable to limit variations of both the input and output common-mode voltages of the differential input and output signals, which can occur across supply voltage variations, temperature variations, and global and local processing variations. The need to control the input and output common-mode voltage of differential signals is becoming increasingly critical as lower supply voltages are being utilized to bias differential amplifier circuits fabricated in new silicon technologies. Moreover, random device mismatches in a differential amplifier circuit can result in large variations in the offset and in the common-mode of the output signals, and adversely affect circuit performance.

### SUMMARY

In one embodiment of the invention, an amplifier circuit includes differential input nodes having first and second differential input nodes, a differential amplifier stage having differential input terminals and differential output terminals, and an input common-mode voltage adaptation circuit connected between the differential input nodes of the amplifier circuit and the differential input terminals of the differential amplifier stage. During an input common-mode adaptation phase, the input common-mode voltage adaptation circuit forces the differential input terminals of the differential amplifier stage to have a common-mode voltage equal to an adaptive reference voltage, independent of a common-mode voltage applied to the differential input nodes of the amplifier circuit during the input common-mode adaptation phase. During a normal period of operation of the amplifier circuit, the input common-mode voltage adaptation circuit maintains the common-mode voltage at the differential input terminals of the differential amplifier stage equal to the adaptive reference voltage, independent of an input differential voltage applied during the normal period of operation.

Other embodiments of the invention will become apparent.

### DESCRIPTION OF THE FIGURES

FIG. 1A is a schematic circuit diagram of a differential amplifier circuit having an input common-mode voltage adaptation circuit, according to an embodiment of the invention.

FIG. 1B is a timing diagram showing control signals for operating the input common-mode voltage adaptation circuit of the differential amplifier circuit shown in FIG. 1A, according to an embodiment of the invention.

FIG. 2 is a schematic circuit diagram of a differential amplifier circuit having an input common-mode voltage adaptation circuit, according to another embodiment of the invention.

FIG. 3 is a schematic circuit diagram of a differential amplifier circuit having an input common-mode voltage adaptation circuit, according to another embodiment of the invention.

FIG. 4A is a schematic circuit diagram of a differential amplifier circuit having an output common-mode feedback control circuit, according to an embodiment of the invention.

FIG. 4B is a timing diagram showing control signals for operating the output common-mode feedback control circuit of the differential amplifier circuit shown in FIG. 4A, according to an embodiment of the invention.

FIG. 5 is a schematic block diagram of a system-on-chip having a differential amplifier circuit with input and output common-mode voltage adaptation and control circuitry, according to an embodiment of the invention.

### WRITTEN DESCRIPTION

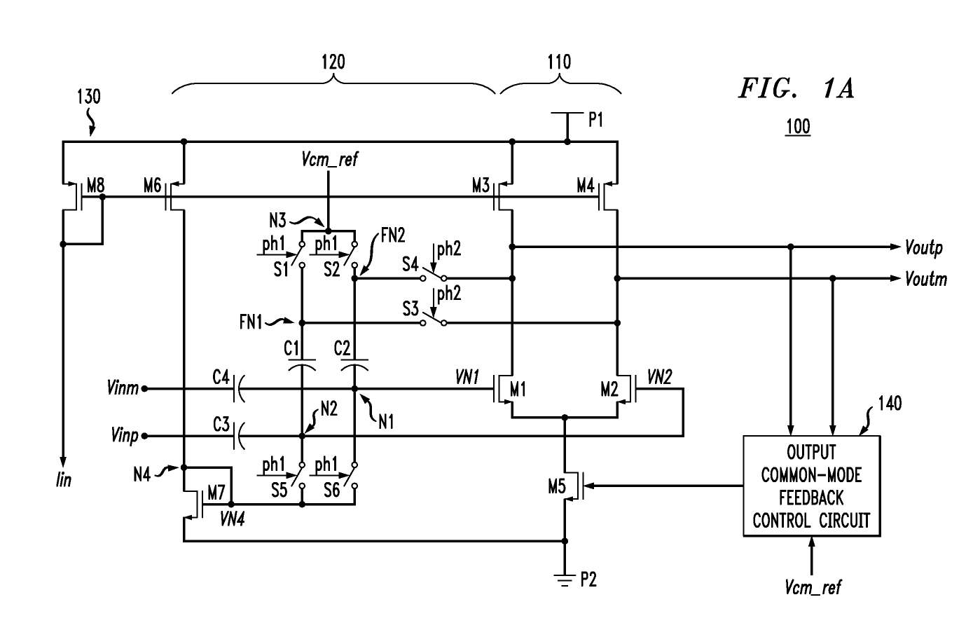

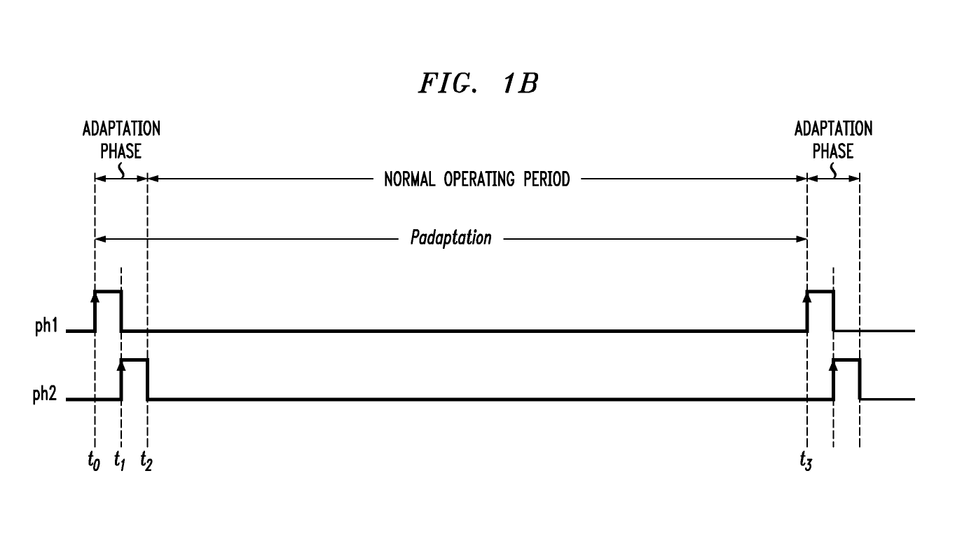

FIG. 1A is a schematic circuit diagram of a differential amplifier circuit having an input common-mode voltage adaptation circuit, according to an embodiment of the invention. In particular, FIG. 1A illustrates a differential amplifier circuit 100 comprising first and second differential input nodes Vinp and Vinm, first and second differential output nodes Voutp and Voutm, a first supply voltage node P1, a second supply voltage node P2, a differential amplifier stage 110, an input common-mode voltage adaptation circuit 120, a current mirror 130, and an output common-mode feedback control circuit 140. In general, the differential amplifier stage 110 comprises a plurality of field effect transistors M1, M2, M3 M4, and M5. The input common-mode voltage adaptation circuit 120 comprises transistors M6 and M7, a plurality of capacitors C1, C2, C3 and C4, and a plurality of switches S1, S2, S3, S4. The current mirror circuit 130 comprises a diode-connected transistor M8 that biases transistors M6, M3 and M4 with a reference bias current Iin. In one embodiment of the invention, the transistors M1, M2, M3, M4, M5, M6, M7 and M8 are MOSFETs (metal oxide semiconductor field effect transistors). In one embodiment, the transistors M3, M4, M6 and M8 are PMOS transistors with 1:1 PMOS current mirror ratios.

The differential amplifier stage 110 comprises a differential transistor pair formed by transistors M1 and M2. In one embodiment, the transistors M1 and M2 are NMOS transistors having gate terminals connected to respective nodes N1 and N2 (first and second output nodes of the input common-mode voltage adaptation circuit 120), source terminals connected together, and drain terminals connected to respective first and second differential output nodes Voutp and Voutm. In one embodiment, the transistors M3 and M4 are PMOS transistors that serve as active load devices for the differential transistor pair M1 and M2, wherein transistor M3 is connected between the first power supply node P1 and the first differential output node Voutp, and wherein transistor M4 is connected between the first power supply node P1 and the second differential output node Voutm. In one embodiment, the transistor M5 is an NMOS tail transistor that is connected to the source terminals of transistors M1 and M2 and the second power supply node P2. In another embodiment of the invention, the PMOS and NMOS devices of the differential amplifier stage 110 are cascoded to improve output impedance.

The differential amplifier stage 110 differentially amplifies (subtracts and multiplies) voltages at nodes N1 and N2 (i.e., VN1−VN2) which are applied to the gate terminals of transistors M1 and M2, respectively. An input common-mode voltage V_{ICM} of the differential amplifier stage 110 is

$$\frac{VN 1 + VN 2}{2} .$$

In general, in one embodiment of the invention, the input common-mode voltage adaptation circuit 120 adaptively controls an input common-mode voltage that is applied to the differential inputs of the differential amplifier stage 110. Without the input common-mode voltage adaptation circuit 120, the input common-mode voltage at the input of the differential amplifier stage 110 would be

$$\frac{Vinp + Vinm}{2} ,$$

which could vary significantly depending on various factors such as, e.g., an output common-mode voltage of an upstream circuit, as well as supply voltage variations, temperature variations, and global and local processing variations.

A differential amplifier circuit it typically designed to operate over a defined range of input common-mode voltages, which depends on the supply rail voltages used in the circuit design. If the input common-mode voltage falls outside this range, the differential amplifier circuit will not operate properly. In fact, there is an optimal common-mode voltage at the gate terminals of the input differential transistor pair that maximizes the performance of the amplifier circuit. This optimal common-mode voltage is not a universal constant. Rather, the optimal voltage varies with conditions of temperature, supply voltage, and manufacturing process. The input common-mode voltage adaptation circuit 120 adapts to changing conditions to always generate a near optimal input common-mode voltage, even as the desired optimal voltage changes with the conditions. As explained in further detail below, in one mode of operation, the input common-mode voltage adaptation circuit 120 adaptively controls the input common-mode voltage at the gate terminals of transistors M1 and M2 independently of the input common-mode voltage of a differential signal received from an upstream circuit, to ensure optimal operation of the differential amplifier circuit 100 across supply voltage variations, temperature variations, and global and local processing variations.

The output common-mode feedback control circuit 140 has inputs connected to the first and second differential output nodes Voutp and Voutm of the differential amplifier circuit 100, and an output that drives a gate terminal of the transistor M5 of the differential amplifier stage 110. In general, the output common-mode feedback control circuit 140 operates by controlling the output common-mode voltage

$${V}_{OCM} = \frac{Voutp + Voutm}{2}$$

of the first and second differential output nodes of the differential amplifier circuit 100. In one embodiment of the invention, the output common-mode feedback control circuit 140 operates by driving the gate terminal of the tail transistor M5 with a voltage that is adjusted over time to maintain the output common-mode voltage at the target level of a common-mode reference voltage Vcm_ref that is input to the output common-mode feedback control circuit 140.

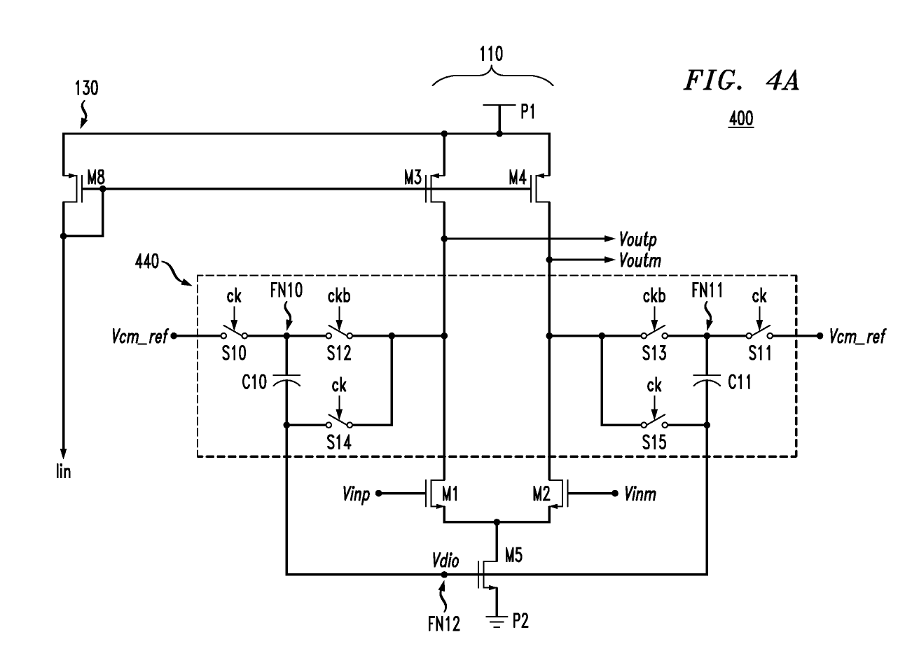

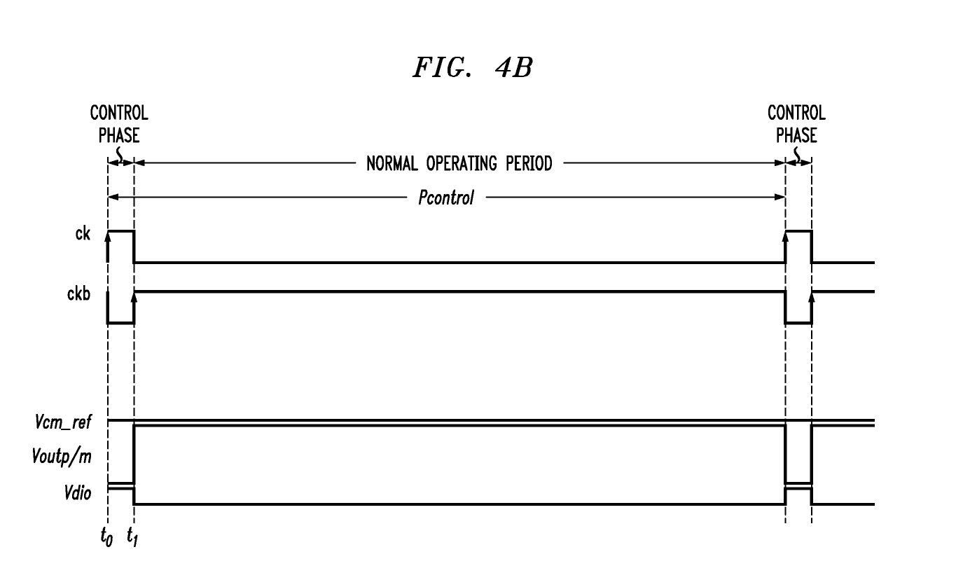

Even when the input common-mode voltage is sufficiently controlled, the output common-mode voltage of the differential amplifier stage 110 can significantly vary over supply voltage variations, temperature variations, and global and local processing variations, which can adversely affect operation of downstream circuitry connected to the output of the differential amplifier circuit 100. In this regard, in one embodiment of the invention, the output common-mode feedback control circuit 140 is implemented to adaptively control the output common-mode voltage. The output common-mode feedback control circuit 140 may be implemented using feedback control circuits and frameworks known to those of ordinary skill in the art. In one embodiment of the invention, the output common-mode feedback control circuit 140 is implemented using the output common-mode feedback control circuit described below with reference to FIGS. 4A and 4B.

Furthermore, as explained below, in another mode of operation, the input common-mode voltage adaptation circuit 120 operates in conjunction with the output common-mode feedback control circuit 140 during an adaptation phase to slightly adjust the input voltages VN1 and VN2 at the gate terminals of the differential transistor pair M1 and M2 to reduce or otherwise eliminate any offset voltage and accommodate any residual mismatch between the output common-mode voltage and the reference voltage Vcm_ref, while maintaining the common-mode voltage at the gates of the differential transistor pair M1 and M2 equal to the adaptive reference voltage, VN4. The circuit architecture and operational mode of the input common-mode voltage adaptation circuit 120 of FIG. 1A will now be discussed in further detail.

As shown in FIG. 1A, the input common-mode voltage adaptation circuit 120 is connected to the first and second differential input nodes Vinp and Vinm of the differential amplifier circuit 100, and to the first and second differential output nodes Voutp and Voutm of the differential amplifier circuit 100. The first and second output nodes N1 and N2 of the input common-mode voltage adaptation circuit 120 are connected to respective gate terminals of transistors M1 and M2 of the differential amplifier stage 110. The input common-mode voltage adaptation circuit 120 comprises a reference voltage node N3 that receives as input a common-mode reference voltage Vcm_ref. In one embodiment as shown in FIG. 1A, the same common-mode reference voltage Vcm_ref is input to both the input common-mode voltage adaptation circuit 120 and the output common-mode feedback control circuit 140.

As further shown in the embodiment of FIG. 1A, a first switch S1 is connected between the reference voltage node N3 and a first feedback node FN1. A second switch S2 is connected between the reference voltage node N3 and a second feedback node FN2. A third switch S3 is connected between the first feedback node FN1 and the second differential output node Voutm. A fourth switch S4 is connected between the second feedback node FN2 and the first differential output node Voutp. A first capacitor C1 is connected between the first feedback node FN1 and the second output node N2. A second capacitor C2 is connected between the second feedback node FN2 and the first output node N1. A third capacitor C3 is connected between the first differential input node Vinp and the second output node N2. A fourth capacitor C4 is connected between the second differential input node Vinm and the first output node N1. The transistor M7 is a diode-connected NMOS transistor that is connected between a reference voltage node N4, and the second power supply node P2. A fifth switch S5 is connected between the reference voltage node N4 and the second output node N2. A sixth switch S6 is connected between the reference voltage node N4 and the first output node N1. The transistor M6 is a PMOS transistor that is connected between the reference voltage node N4 and the first power supply node P1. The transistor M6 generates a current (mirror current of Iin) to bias the diode-connected transistor M7.

In one embodiment of the invention, the input common-mode voltage adaptation circuit 120 is operated by a plurality of control signals, ph1 and ph2, which are generated by a clock circuit to switchably control switches S1, S2, S3, S4, S5, and S6. More specifically, in the embodiment of FIG. 1A, a first control signal ph1 is applied to control switches S1, S2, S5, and S6, and a second control signal ph2 is applied to control switches S3 and S4. FIG. 1B is a timing diagram showing control signals ph1 and ph2 for operating the input common-mode voltage adaptation circuit of the differential amplifier circuit shown in FIG. 1A, according to an embodiment of the invention. As shown in FIG. 1B, control signals ph1 and ph2 are short duration pulses that are sequentially applied during an input common-mode voltage adaptation phase (or “adaptation phase”) in which the input common-mode voltage adaptation circuit 120 outputs an adaptive input common-mode voltage at nodes N1 and N2, which is input to the gate terminals of the differential transistor pair M1 and M2 of the differential amplifier stage 110. As further shown in FIG. 1B, the control signals ph1 and ph2 are sequentially applied during an adaption phase (e.g., time period from t₀ to t₂), wherein a first control signal ph1 (or first control pulse) is applied during first portion of the adaptation phase (e.g., time period from t₀ to t₁), and a second control signal ph2 (or second control pulse) is applied during a second portion of the adaption phase (e.g., time period from t₁ to t₂).

During an adaption phase, the upstream circuitry, which is connected to the first and second differential input nodes Vinp and Vinm the differential amplifier circuit 100, is controlled to output a differential signal where the voltages on the first and second differential input nodes Vinp and Vinm are the same. In this regard, during an adaptation phase, the differential voltage Vinp−Vinm=0, and the input common-mode voltage V_{ICM}=Vinp=Vinm. During an adaptation phase, the input common-mode voltage adaptation circuit 120 generally operates in response to sequential assertion of control pulses ph1 and ph2 to force the input common-mode voltage at the input to the differential amplifier stage 110 to be equal to a target adaptive reference voltage VN4 on node N4, which is an adaptive cascode bias voltage generated by the diode-connected NMOS transistor M7.

After completion of an adaption phase, a “normal operating period” ensues in which neither control pulse ph1 and ph2 is asserted and a differential signal froth the upstream circuit is applied to the differential input nodes Vinm and Vinp of the differential amplifier circuit 100. In FIG. 1B, a “normal operating period” is shown from time t₂ to time t₃, and another adaptation phase begins at time t₃. In one embodiment of the invention, an adaptation phase is periodically repeated at a given period of time, P_{adaptation}, which is shown in FIG. 1B as a time period equal to t₃-t₀. An adaptation phase according to an embodiment of the invention will now be discussed in greater detail with reference to FIGS. 1A and 1B.

At the start of a first portion of an adaptation phase (e.g., time t₀), a control pulse ph1 is applied to activate (close) switches S1, S2, S5 and S6, while switches S3 and S4 are deactivated (open). When switches S1, S2, S5, and S6 are activated (closed), the common-mode reference voltage Vcm_ref is applied to the feedback nodes FN1 and FN2, and the output nodes N1 and N2 are connected to the reference voltage node N4. In this regard, during the first portion of the adaptation phase (as control signal ph1 remains asserted), an adaptive cascode bias voltage on node N4, which is generated by the diode-connected NMOS transistor M7, is applied to the gate terminals of differential transistor pair M1 and M2. The adaptive cascode bias voltage (adaptive reference voltage VN4) on node N4 is an optimal input common-mode voltage that is applied to the gate terminals of the different transistor pair M1 and M2. In this state, since the adaptive reference voltage VN4 is applied to both gate terminals of the differential transistor pair M1 and M2 (i.e., VN1 and VN2=VN4), a zero (0) differential voltage is applied at the input of the differential amplifier stage 110.

Furthermore, during the first portion of the adaptation phase, each of the first and second capacitors C1 and C2 are precharged to a steady state voltage level of Vcm_Ref−VN4. In addition, the third capacitor C3 is precharged to a steady state voltage level of Vinp−VN4, and the fourth capacitor C4 is precharged to a steady stage voltage level of Vinm−VN4.

The term “cascode bias voltage” refers to the fact that (a) the voltage on node N4 is independent of the input signals, Vinp and Vinm, and that (b) the sizes of transistors M6 and M7 are designed such that the voltage on node N4 is large enough to cause the voltage on the drain terminal of transistor M5 to be large enough to keep transistor M5 in the saturation region of operation. The term “adaptive” refers to the fact that the adaptive reference voltage on node N4 adapts with variations in voltage, temperature, and processing conditions. Due to matching of transistors M7, M1, and M2, and matching of transistors M6, M3, and M4, by design, the variations in the adaptive reference voltage VN4 are correlated with the variations in the differential amplifier circuit. As a result, the adaptive reference voltage VN4 is maintained at a near-optimal voltage for maximizing the differential circuit performance. In one embodiment of the invention, the transistors M7, M1, and M2 are matched in polarity (e.g., NMOS transistors) and sized accordingly (e.g., the width-to-length ratio of transistor M7 is ¼ the width-to-length ratio of transistors M1 and M2), and the transistors M6, M3, and M4 are matched in polarity (e.g. PMOS transistors) and sized appropriately (e.g. the width and length of transistor M6 are equal to the widths and lengths, respectively, of transistors M3 and M4) to provide a target adaptive cascade bias voltage.

In this regard, since transistor M7 is matched to transistors M1 and M2 by design, any affect that variation of temperature or processing has on transistor M7 will be matched to transistors M1 and M2. Similarly, any effect that variation of temperature or processing has on transistor M6 will be matched to transistors M3 and M4. While the adaptive reference voltage VN4 is fixed at an optimal level for a given adaptation phase, the adaptive reference voltage VN4 can change over time in subsequent adaptation phases to adapt to variations in process, voltage or temperature conditions. In practice, since supply voltage and temperature drift relatively slowly over normal operating periods of the circuit, the common-mode of the inputs of the differential transistor pair M1 and M2 can be fixed between successive adaption phases without adversely affecting circuit performance and the duration of the normal operating phase can be large relative to the duration of the adaptation phases, ph1 and ph2.

Next, at the start of the second portion of the adaptation phase (e.g., time t₁), the control pulse ph1 is de-asserted to deactivate (open) switches S1, S2, S5 and S6, and a control pulse ph2 is asserted to activate (close) switches S3 and S4. With switches S1, S2, S5, and S6 deactivated, the common mode reference voltage Vcm_ref at node N3 is disconnected from the feedback nodes FN1 and FN2, and the adaptive reference voltage VN4 on node N4 is disconnected from nodes N1 and N2. Moreover, with switches S3 and S4 activated (closed), the feedback nodes FN1 and FN2 are connected to the second and first differential output nodes Voutm and Voutp, respectively, of the differential amplifier circuit 100. In this instance, the capacitors C1 and C2 are connected across the drain and gate terminals of respective differential input transistors M2 and M1, respectively, thereby providing negative feedback by capacitive coupling of the output (drain) terminals to the input (gate) terminal.

In this state, during the second portion of the adaptation phase, the input common-mode voltage adaptation circuit 120 operates to slightly adjust the voltages VN1 and VN2 at the inputs of the differential amplifier stage 110 to generate a small differential input voltage to perform offset cancellation, while preserving the average input adaptive common-mode voltage applied to the inputs of the differential amplifier stage 110. At the end of the first portion of the adaptation phase, the voltages VN1=VN2=VN4 such that a zero (0) differential voltage is applied to the inputs of the differential amplifier stage 110. In an ideal state where it is assumed that there is no mismatch between transistors M1 and M2, and no mismatch between load transistors M3 and M4, the differential amplifier stage 110 would generate a zero (0) differential output signal with Voutp=Voutm (i.e., Voutp−Voutm=0) when a zero differential input signal is applied to the input terminals of the differential transistor pair M1 and M2. However, in practice, a slight mismatch between transistors M1 and M2 and/or a slight mismatch between transistors M3 and M4 would result in an “offset voltage” at the differential output nodes Voutp and Voutm. As is known in the art, the term “offset voltage” is a non-zero differential output voltage that is generated by the differential amplifier stage 110 when the differential input voltage is zero (0). While the output common-mode feedback control circuit 140 operates during the second portion of the adaptation phase to force the output common-mode voltage

$${V}_{OCM} = \frac{Voutp + Voutm}{2}$$

to be equal to the common-mode reference voltage Vcm_ref, the input common-mode voltage adaptation circuit 120 operates to reduce or otherwise eliminate any offset voltage at the output of the differential amplifier stage 110.

In particular, during the second portion of the adaptation phase, the output common-mode feedback control circuit 140 drives the gate of the tail transistor M5 to adjust the output common-mode voltage

$${V}_{OCM} = \frac{Voutp + Voutm}{2}$$

to be equal to the common-mode reference voltage Vcm_ref As the differential output voltages Voutp and Voutm are adjusted to fix the output common-mode voltage at Vcm_ref the output differential voltage Voutp−Voutm is applied to the feedback nodes FN1 and FN2 by virtue of the negative feedback resulting from the activation of switches S3 and S4. The voltages on the feedback nodes FN1 and FN2 will slightly adjust (increase and decrease) from Vcm_ref to match the difference between the differential output voltages Voutp and Voutm. This slight offset voltage at the feedback nodes FN1 and FN2 will couple through the capacitors C1 and C2 to the gate terminals of transistor pair M1 and M2, thereby creating a small offset between the gate voltages VN1 and VN2, which were both initially set at the adaptive reference voltage VN4 at the end of the first portion of the adaptation phase. The negative feedback connection drives the differential voltage at the output to be equal to the differential voltage at the input of the differential amplifier stage (with negative polarity) and the high-gain of the differential amplifier stage then causes both differential voltages to be driven to almost zero. While the gate voltages VN1 and VN2 may slightly increase and decrease from the initial value of the adaptive reference voltage VN4 to achieve offset voltage cancellation, the input common-mode voltage adaptation circuit 120 operates to maintain the input common-mode voltage

$${V}_{ICM} = \frac{VN 1 + VN 2}{2}$$

at the input of the differential transistor pair M1 and M2 equal to the adaptive reference voltage VN4.

Next, at the end of the second portion of the adaptation phase (e.g., time t₃), the control pulse ph2 is de-asserted to deactivate (open) switches S3 and S4, thereby disconnecting the capacitors C1 and C2 from the differential output nodes Voutp and Voutm in the feedback configuration. When both ph1 and ph2 are disabled, the differential amplifier circuit 100 is available for use and enters into a normal operating period, with the output offset error largely eliminated and the differential amplifier stage 110 adaptively biased for optimal performance. In particular, at the start of the normal operating period (e.g., time t₂), upstream circuitry connected to the differential amplifier circuit 100 will generate and output a differential voltage that drives the differential input nodes Vinp and Vinm of the differential amplifier circuit 100.

During the normal operating period, a voltage stored across the capacitors C3 and C4 act as a level-shifter circuit to level-shift the input common-mode voltage at the input nodes Vinp and Vinm (either up or down) to the level of the adaptive input common-mode voltage level at the nodes N1 and N2. In this regard, when a differential signal is applied to the input nodes Vinp and Vinm, the differential signal VN1−VN2 applied to the input terminals of the differential amplifier stage 110 will have an input common-mode voltage fixed at the level of the adaptive reference voltage VN4 generated during the previous adaptation phase. As such, the embodiment of FIG. 1A allows the input common-mode voltage at the input of the differential amplifier stage 110 to be independent of the input common-mode voltage at the differential input nodes Vinp and Vinm of the differential amplifier circuit 100. Therefore, the differential amplifier circuit 100 can tolerate a wide range of input common-mode voltages provided by upstream circuitry, without adversely affecting the performance of the differential amplifier stage 110.

Moreover, as noted above, the input common-mode voltage at the input of the differential transistor pair M1 and M2 adapts to the process parameters of the individual instance of the circuit and adapts periodically to changing conditions of power supply voltage and temperature. This adaptation maintains optimal biasing for the differential amplifier stage 110. As shown in FIG. 1B, the control pulses ph1 and ph2 are pules of relatively short duration. For example, the first control pulse ph1 has a duration of t₁-t₀, and the second control pulse ph2 has a duration of t₂-t₁. In one embodiment of the invention, the period of the control pulses ph1 and ph2 are on the order of nanoseconds, e.g., in a range of about 1-10 nanoseconds. Moreover, in one embodiment of the invention, the period of adaptation, Padaptation, is on the order of 1-10 microseconds. The duration of the control pulses ph1 and ph2 and the period of adaptation, Padaptation, are application specific, and can be varied as necessary, depending on the application and the given fabrication technology. As noted above, the adaptation phase is periodically performed to adapt the input common-mode voltage to an ideal level since environmental conditions such as supply voltage and temperature can change during operation. Moreover, adaptation can be performed periodically to refresh the input common-mode voltage in response to other circuit anomalies such as capacitor leakage current.

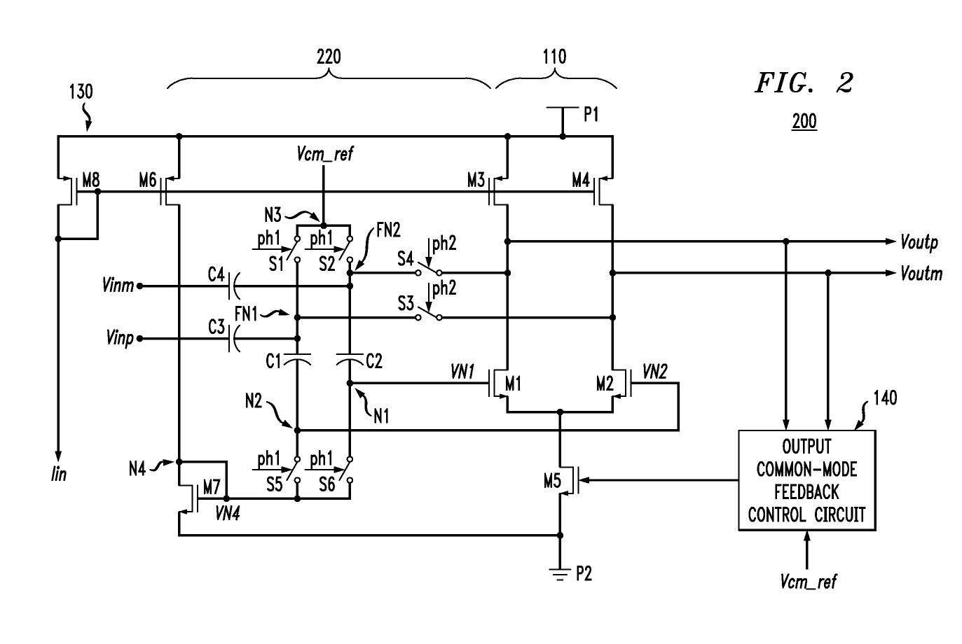

FIG. 2 is a schematic circuit diagram of a differential amplifier circuit having an input common-mode voltage adaptation circuit, according to another embodiment of the invention. In particular, FIG. 2 illustrates a differential amplifier circuit 200 comprising first and second differential input nodes Vinp and Vinm, first and second differential output nodes Voutp and Voutm, a first supply voltage node P1, a second supply voltage node P2, a differential amplifier stage 110, an input common-mode voltage adaptation circuit 220, a current mirror 130, and an output common-mode feedback control circuit 140. The differential amplifier circuit 200 of FIG. 2 is similar in structure and operation of the differential amplifier circuit 100 of FIG. 1A, so a detailed discussion of the architecture and operation of the differential amplifier circuit 200 will not be repeated.

In the embodiment of FIG. 2, the input common-mode voltage adaptation circuit 220 is similar in structure and operation of the input common-mode voltage adaptation circuit 120 discussed above, except that in the embodiment of FIG. 2, the third capacitor C3 is connected between the differential input node Vinp and the first feedback node FN1, and the fourth capacitor C4 is connected between the differential input node Vinm and the second feedback node FN2. In this embodiment, the input common-mode voltage adaptation circuit 220 operates in the same manner as the input common-mode voltage adaptation circuit 120 during the first portion of an adaptation phase, ph1 (as discussed above with reference to FIG. 1B). During the second portion of the adaptation phase, ph2, however, the offset cancellation is improved relative to the embodiment of FIG. 1A due to the fact that the capacitors C3 and C4 are not connected to the input nodes N1 and N2 of the differential transistor pair M1 and M2. During a normal operating period, when every switch S1, S2, S3, S4, S5, and S6 is deactivated (open), in the embodiment of FIG. 2, the capacitors C3 and C1 are serially connected between the input differential node Vinp and the node N2 at the input to transistor M2, and the capacitors C4 and C2 are serially connected between the input differential node Vinm and the node N1 at the input to transistor M1.

In this embodiment, the effective capacitance series capacitors C3/C1 between nodes Vinp and N2 is less than the capacitance C3 alone (as in the embodiment of FIG. 1A), and the effective capacitance of the series capacitors C4/C2 between nodes Vinm and N1 is less than the capacitance C3 alone (as in the embodiment of FIG. 1A). In practice, small parasitic capacitances exist at the gate terminals of the transistors M1 and M2. As such, a capacitive voltage divider essentially exists at the input terminal of each transistor M1 and M2, which effectively attenuates the voltage signal at the input terminals of the transistors M1 and M2 based on a ratio of the effective capacitance to the parasitic capacitance.

In an embodiment where the values of the capacitors C1, C2, C3, and C4 are on the order of about 0.1 pf, there can be significant attenuation of the input signal, which reduces the gain of the differential amplifier stage 110. However, as explained above, the embodiment of FIG. 2 provides more offset cancellation (as compared to the embodiment of FIG. 1A), thereby enhancing the performance of the overall differential amplifier circuit 100 with respect to offset cancellation, at the tradeoff of lower gain.

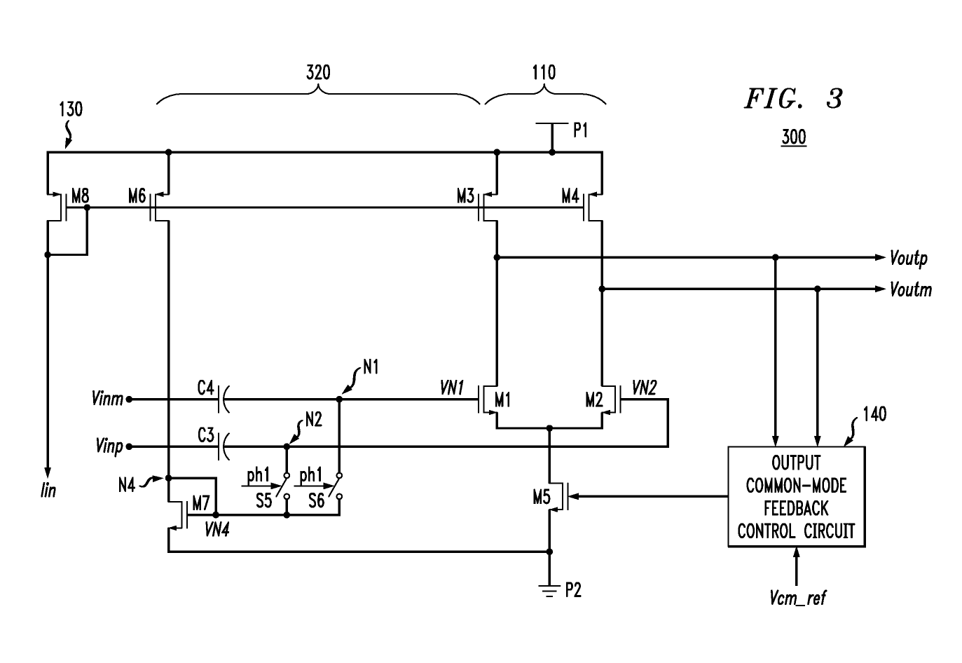

FIG. 3 is a schematic circuit diagram of a differential amplifier circuit having an input common-mode voltage adaptation circuit, according to another embodiment of the invention. In particular, FIG. 3 illustrates a differential amplifier circuit 300 comprising first and second differential input nodes Vinp and Vinm, first and second differential output nodes Voutp and Voutm, a first supply voltage node P1, a second supply voltage node P2, a differential amplifier stage 110, an input common-mode voltage adaptation circuit 320, a current mirror 130, and an output common-mode feedback control circuit 140. The differential amplifier circuit 300 of FIG. 3 is similar in structure and operation of the differential amplifier circuits 100 and 200 of FIGS. 1A and 2, so a detailed discussion of the architecture and operation of the differential amplifier circuit 300 will not be repeated.

In the embodiment of FIG. 3, the input common-mode voltage adaptation circuit 320 is similar in structure and operation to the input common-mode voltage adaptation circuit 120 discussed above, except that in the embodiment of FIG. 3, the feedback circuitry (switches S1, S2, S3, S4 and capacitors C1 and C3) is not implemented to provide offset cancellation, while the capacitors C3 and C4, switches S5 and S6, and the diode-connected NMOS transistor M7, are implemented to adaptively control the input common-mode voltage at the gate terminals of the differential transistor pair M1 and M2, in a manner as discussed above. In the embodiment of FIG. 3, the input common-mode voltage adaptation circuit 300 operates in response to a control pulse ph1 that is applied during an adaptation phase to activate (close) switches S5 and S6 to connect the output nodes N1 and N2 to the reference voltage node N4, and apply an adaptive reference voltage VN4 to the gate terminals of differential transistor pair M1 and M2, as discussed above with regard to FIG. 1B. However, in the embodiment of FIG. 3, a second portion of the adaptation phase is not implemented. The embodiment of FIG. 4 can be implemented in applications where an offset voltage at the output of the differential amplifier stage 100 does not adversely affect circuit performance.

FIG. 4A is a schematic circuit diagram of a differential amplifier circuit having an output common-mode voltage feedback control circuit, according to an embodiment of the invention. In particular, FIG. 4A illustrates a differential amplifier circuit 400 comprising first and second differential input nodes Vinp and Vinm, first and second differential output nodes Voutp and Voutm, a first supply voltage node P1, a second supply voltage node P2, a differential amplifier stage 110, a current mirror 130, and an output common-mode feedback control circuit 440. The differential amplifier stage 110 and current mirror 130 are similar in structure and operation to those circuits discussed above with reference to FIGS. 1A, 2 and 3, and thus, a detailed discussion is not necessary.

The output common-mode feedback control circuit 440 shown in FIG. 4A is one embodiment of the output common-mode feedback control circuit 140 shown in FIGS. 1A, 2 and 3. As shown in FIG. 4A, the output common-mode feedback control circuit 440 comprises first and second input nodes connected to the first and second differential output nodes Voutp and Voutm of the differential amplifier circuit 400, a reference voltage node Vcm_ref that receives a common mode reference voltage, and an output node FN12 connected to the gate terminal of the tail transistor M5 of the differential amplifier stage 110. The output common-mode feedback control circuit 440 comprises a plurality of switches S10, S11, S12, S13, S14, and S15, and a plurality of capacitors C10 and C11.

The switch S10 is connected between the reference voltage node Vcm_ref and a first feedback node FN10. The switch S11 is connected between the reference voltage node Vcm_ref and a second feedback node FN11. The switch S12 is connected between the first feedback node FN10 and the first differential output node Voutp (which is the first input node of the output common-mode feedback control circuit 440). The switch S13 is connected between the second feedback node FN11 and the second differential output node Voutm (which is the second input node of the output common-mode feedback control circuit 440). The switch S14 is connected between the first differential output node Voutp and the output node FN12. The switch S15 is connected between the second differential output node Voutm and the output node FN12. A first capacitor C10 is connected between the first feedback node FN10 and the output node FN12, and a second capacitor C11 is connected between the second feedback node FN11 and the output node FN12. A gate terminal of the tail transistor M5 is connected to the output node FN12.

The output common-mode feedback control circuit 440 generates a control voltage Vdio on the output node FN12 to drive the tail transistor M5 of the differential amplifier stage 110 in order to adjust an output common-mode voltage

$${V}_{OCM} = \frac{Voctp + Voutm}{2}$$

to be equal to the reference voltage Vcm_ref. In one embodiment of the invention, the output common-mode feedback control circuit 440 is operated by a plurality of control signals, ck and ckb, which are generated by a clock circuit to switchably control switches S10, S11, S12, S13, S14, and S15. More specifically, in the embodiment of FIG. 4A, a first control signal ck is applied to control switches S10, S11, S14, and S15, and a second control signal ckb is applied to control switches S12 and S13.

FIG. 4B is a timing diagram showing control signals ck and ckb for operating the output common-mode feedback control circuit 440 of FIG. 4A, according to an embodiment of the invention. As shown in FIG. 4B, control signals ck and ckb are concurrent pulses of opposite polarity (i.e., complementary signals), wherein ck has a small duty cycle over a control period, P control. FIG. 4B further illustrates voltage waveforms of Vcm_ref, Voutp/m and Vdio, during different periods of operation (Control Phase and Normal Operating Period) of the output common-mode feedback control circuit 440 and differential amplifier circuit 400.

As shown in FIG. 4B, at the start of a control phase (e.g., time t₀), the control signal ck is asserted (logic “1”), and the control signal ckb is de-asserted (logic “0”). In this state, during the control phase, the switches S10, S11, S14 and S15 are activated (closed) and the switches S12 and S13 are deactivated (open). Further, the gate terminal of the tail transistor M5 (connected to the output node FN12) is coupled to both the first and second differential output nodes Voutp and Voutm, temporarily placing the tail transistor M5 into a diode-connected NMOS configuration. Moreover, the first capacitor C10 is connected between the reference voltage node Vcm_ref and the output node FN12 (and first differential output node Voutp), and the second capacitor C11 is connected between the reference voltage node Vcm_ref and the output node FN12 (and second differential output node Voutm). During the control phase, the first and second capacitors C10 and C11 are pre-charged to Vcm_ref−Vdio, wherein the voltage Vdio=Voutp=Voutm, since Voutp is connected to Voutm and to FN12 through switches S14 and S15. During the control phase, the voltage Vdio applied to the gate terminal of the tail transistor M5 is a well-controlled voltage that is essentially equal to the diode voltage of the tail transistor M5. The voltages of the output nodes, Voutp and Voutm, are also well controlled since they are equal to Vdio. This is an important feature in some applications because uncontrolled voltage at the output nodes may result in over-voltage stress on downstream devices connected to Voutp and Voutm. Both in the control phase and in the normal operating phase, the common-mode voltage of the input to the differential transistor pair M1 and M2 should to be within a range that allows for proper operation. In fact, an optimal common-mode voltage exists that maximizes the performance of the differential amplifier and it is desirable, but not necessary, for the common-mode voltage to be near optimal. In one embodiment, during the control phase, the upstream circuit is controlled such that there is zero differential voltage at the input of the differential amplifier so that Vinp=Vinm.

At the end of the control phase, the control signal ck is de-asserted, and the complementary control signal ckb is asserted, which begins a normal operating period. In the normal operation period, switches S10, S11, S14, and S15 are deactivated (opened) and switches S12 and S13 are activated (closed). In the normal operating period, the first capacitor C10 is connected between the first differential output node Voutp and the output node FN12 (gate terminal of transistor M5), and the second capacitor C11 is connected between the second differential output node Voutm and the output node FN12. In this state, the capacitors C10 and C11 form an averaging circuit whereby the charge of the capacitors C10 and C11 is redistributed between them, but the average charge stored in C10 and C11 does not change. The current in tail transistor M5 must be equal to the sum of the currents in PMOS transistors M3 and M4. Therefore, a small change in the gate voltage Vdio of tail transistor M5 causes a large change of the opposite polarity in the common-mode voltage of Voutp and Voutm. During the normal operating phase, the capacitive coupling of Voutp and Voutm to the gate of tail transistor M5 through capacitors C10 and C11 forms a negative feedback path and a high-gain negative feedback loop. When the control signal ckb is asserted, because of this high-gain negative feedback loop, the voltage Vdio adjusts slightly at the start of the normal operating phase until the common-mode voltage of Voutp and Voutm is equal to Vcm_ref.

While the control signal ck remains de-asserted and the control signal ckb remains asserted during the normal operating period, the gate voltage Vdio of tail transistor M5 is adjusted so that the output common-mode voltage is maintained substantially equal to the reference voltage Vcm_ref. As the voltages of the differential input signals Vinp and Vinm vary in differential and/or input common-mode voltage, the gate voltage Vdio of tail transistor M5 is continuously adjusted to maintain the output common-mode voltage equal to Vcm_ref.

The embodiment of FIG. 4A provides an output common-mode feedback control circuit architecture that uses low current (low power) and has a small footprint, as compared to other conventional output common-mode voltage circuit architectures. For example, some conventional circuits implement a current mirror (diode-connected transistor) that is connected to the tail transistor of the differential amplifier stage to generate a control voltage that drives the gate of the tail transistor. In this conventional framework, the current mirror and tail transistor must be large channel length devices for purposes of matching, wherein effective matching is accomplished by using devices with channel lengths that are many times greater than a minimum channel length as would be necessary except for the purpose of achieving a desired matching ability. In the embodiment of FIG. 4A, no current mirror is implemented to drive the voltage on the gate of the tail transistor M5, thus resulting in control circuitry using lower power and having a smaller footprint.

Furthermore, by eliminating the need to match the tail transistor M5 to a current mirror transistor, the size/area of the tail transistor M5 can be significantly reduced. This reduction in size/area of the tail transistor M5 results in reduced parasitic capacitance at the gate node (output node FN12) of the tail transistor M5. Moreover, this reduced parasitic capacitance results in increase gain of the common mode feedback loop.

Furthermore, during a control phase when the control signal ck is active, the output common-mode voltage is well controlled because the output voltages Voutp and Voutm are equal to the gate voltage Vdio. As noted above, the voltage Vdio is a well-controlled voltage because it is the diode voltage of the NMOS tail transistor M5. This is in contrast to conventional circuits in which the output common mode voltage can vary a lot before adjustment, which is not desirable for certain applications.

Moreover, since there are no matching considerations for the NMOS tail transistor M5, the tail transistor M5 can have a shorter channel length, higher transconductance and smaller device parasitic capacitance. As a result, the common-mode control accuracy and bandwidth are improved. Moreover, small capacitors can be implemented for the first and second capacitors C10 and C11. In one embodiment, the differential amplifier stage 110 is a moderate to high-speed circuit with bias currents on the order of hundreds of μ amperes. For example, assume the NMOS tail transistor M5 has a bias current of 160 μA with 80 μA flowing through each PMOS load transistors M3 and M4. With this amount of bias current, during the control phase, the effective resistance for charging the capacitors C10 and C11 (1/gm of the NMOS tail transistor M5) is relatively small. This small effective charging resistance, together with small capacitance values of capacitors C10 and C11, results in a short RC time constant for charging the capacitors C10 and C11 during the control phase. With a faster charge time for the capacitors C10 and C11, the duration of the control phase (i.e., the pulse width of the asserted control signal ck) can be short, resulting in reduced time that the differential amplifier circuit is not operating in the normal operating mode.

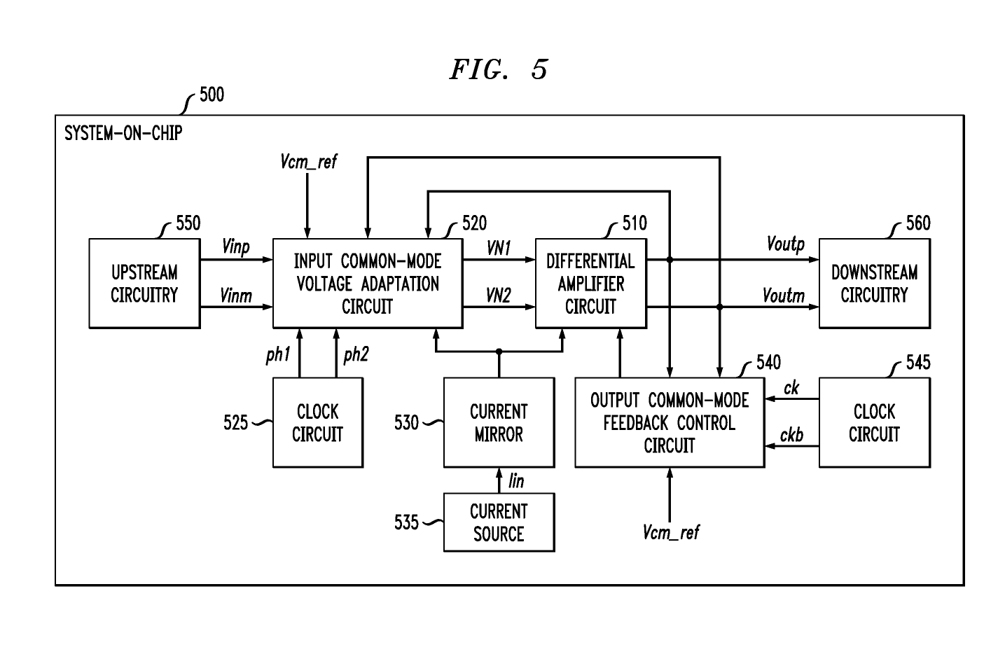

Embodiments of the invention as shown in FIGS. 1A, 2, 3, and 4A may be implemented in the form of integrated circuits. In an integrated circuit implementation, identical dies are typically formed in a repeated pattern on a surface of a semiconductor wafer. Each die includes one or more circuit cores and circuitry as described herein, and may include other structures or circuits. For example, the system-on-chip shown in FIG. 5 is an example of a semiconductor chip or die comprising a plurality of integrated circuits. The individual die are cut or diced from the wafer, and then each die is packaged as an integrated circuit. One skilled in the art would know how to dice wafers and package die to produce integrated circuits. Integrated circuits so manufactured are considered embodiments of this invention.

Moreover, embodiments of the invention as shown in FIGS. 1A, 2, 3, and 4A can be implemented in the form of integrated circuits of a system-on-chip. FIG. 5 is a schematic block diagram of a system-on-chip having a differential amplifier circuit with input and output common-mode voltage adaptation and control circuitry, according to an embodiment of the invention. FIG. 5 illustrates a system-on-chip 500 comprising a differential amplifier circuit 510, an input common-mode voltage adaptation circuit 520, a first clock circuit 525, a current mirror circuit 530, a current source 535, an output common-mode feedback control circuit 540, a second clock circuit 545, upstream circuitry 550, and downstream circuitry 560. The differential amplifier 510 can be implemented using the embodiments of the differential amplifier stage 110 shown in FIGS. 1A, 2, 3, and 4A, for example, or using other differential amplifier circuit frameworks known in the art. The input common-mode voltage adaptation circuit 520 can be implemented using any one of the input common-mode voltage adaptation circuit embodiments 120, 220 or 320 shown in FIGS. 1A, 2 and 3 for example. The first clock circuit 525 can be implemented using any control logic or clock circuit to generate the control signals ph1 and ph2 (or just ph1) for controlling operation of the input common-mode voltage adaptation circuit 520, such as discussed above with reference to FIG. 1B.

In one embodiment of the invention, the current mirror circuit 530 can be implemented using any suitable current mirror circuit framework, such as a single diode-connected transistor 130 as shown in FIGS. 1A, 2, 3, and 4A, for example. The current source 535 may be implemented using any circuit that generates a reference current Iin, which is mirrored by the current mirror circuit 530 to generate bias currents for operating components of the input common-mode voltage adaptation circuit 520 and the differential amplifier circuit 510, for example.

In one embodiment of the invention, the output common-mode voltage feedback control circuit 540 can be implemented using the output common-mode feedback control circuit 440 shown in FIG. 4A. The second clock circuit 545 can be implemented using any logic or clock circuit to generate the control signals ck and ckb for controlling operating operation of the output common-mode voltage feedback control circuit 540, as discussed above with reference to FIG. 4B.

A system-on-chip having embodiments of differential amplifier circuits with input and/or output common mode adaptation and control circuitry, such as shown in FIGS. 1A, 2, 3 and 4A, can be implemented in a wide range of applications and state of the art technologies in which a high-performance differential amplifier is required. For example, in one embodiment of the invention, the system-on-chip 500 may be implemented in a storage device (e.g., hard disk drive device) to control reading and writing of data from and to a hard disk storage medium. In such an embodiment, a differential amplifier circuit such as shown in FIGS. 1A, 2, 3, and 4A can be implemented in high-speed, high-resolution comparator sub-blocks inside an ADC (analog-to-digital converter) circuit in a read-channel analog front-end storage system. In such an embodiment, the upstream circuitry 550 shown in FIG. 5 may comprise an analog read path and the downstream circuitry 560 of FIG. 5 may comprise a quantizer/comparator latch followed by a digital signal processing circuit.

In this regard, although embodiments of the invention have been described herein with reference to the accompanying drawings, it is to be understood that embodiments of the invention are not limited to the described embodiments, and that various changes and modifications may be made by one skilled in the art resulting in other embodiments of the invention within the scope of the following claims.

What is claimed is:

1. An amplifier circuit, comprising:
differential input nodes comprising first and second differential input nodes;
a differential amplifier stage comprising differential input terminals and differential output terminals; and
an input common-mode voltage adaptation circuit connected between the differential input nodes of the amplifier circuit and the differential input terminals of the differential amplifier stage,
wherein during an input common-mode adaptation phase, the input common-mode voltage adaptation circuit forces the differential input terminals of the differential amplifier stage to have a common-mode voltage equal to an adaptive reference voltage, independent of a common-mode voltage applied to the differential input nodes of the amplifier circuit during the input common-mode adaptation phase, and
wherein during a normal period of operation of the amplifier circuit, the input common-mode voltage adaptation circuit maintains the common-mode voltage at the differential input terminals of the differential amplifier stage equal to the adaptive reference voltage, independent of an input differential voltage applied during the normal period of operation.

2. The amplifier circuit of claim 1, wherein the input common-mode voltage adaption circuit comprises:
a first output node connected to a first differential input terminal of the differential amplifier stage;
a second output node connected to a second differential input terminal of the differential amplifier stage;
a first capacitor connected between the first differential input node of the amplifier circuit and the first output node;
a second capacitor connected between the second differential input node of the amplifier circuit and the second output node;
an adaptive reference voltage circuit to generate the adaptive reference voltage on a reference voltage node;
a first switch connected between the reference voltage node and the first output node; and
a second switch connected between the reference voltage node and the second output node,
wherein during the input common-mode adaptation phase, the input common-mode voltage adaptation circuit switchably connects the reference voltage node to the first and second output nodes to apply the adaptive reference voltage to both of the first and second differential input terminals of the differential amplifier stage.

3. The amplifier circuit of claim 2, wherein the adaptive reference voltage circuit comprises a diode-connected MOS transistor connected to the adaptive reference voltage node.

4. A system-on-chip comprising the amplifier circuit of claim 1.

5. An amplifier circuit, comprising:
differential input nodes comprising first and second differential input nodes;
a differential amplifier stage comprising differential input terminals and differential output terminals, the differential input terminals comprising first and second differential input terminals and the differential output terminals comprising first and second differential output terminals; and
an input common-mode voltage adaptation circuit connected between the differential input nodes of the amplifier circuit and the differential input terminals of the differential amplifier stage, the input common-mode voltage adaptation circuit comprising:
first and second feedback nodes connected to the first and second differential output terminals of the differential amplifier stage; and
first and second output nodes connected to the first and second differential input terminals of the differential amplifier stage,
wherein during a first portion of an input common-mode adaptation phase, the input common-mode voltage adaptation circuit applies an adaptive reference voltage to both the first and second differential input terminals of the differential amplifier stage to force the differential input terminals to have a common-mode voltage equal to the adaptive reference voltage, independent of a common-mode voltage applied to the differential input nodes of the amplifier circuit during the first portion of the input common-mode adaptation phase, and
wherein during a second portion of the input common-mode adaptation phase, the input common-mode voltage adaptation circuit capacitively couples the first and second differential output terminals of the differential amplifier stage to the first and second differential input terminals of the differential amplifier stage to generate a differential input voltage to perform offset cancellation, while maintaining the common-mode voltage at the differential input terminals of the differential amplifier stage.

6. The amplifier circuit of claim 5, wherein the input common-mode voltage adaption circuit comprises:
a first reference voltage node that receives a common-mode reference voltage;
a first switch connected between the first reference voltage node and the first feedback node;
a second switch connected between the first reference voltage node and the second feedback node;
a third switch connected between the first feedback node and the second differential output terminal;
a fourth switch connected between the second feedback node and the first differential output terminal;
a first capacitor connected between the first feedback node and the second output node;
a second capacitor connected between the second feedback node and the first output node;
a third capacitor connected between the first differential input node and the second output node;
a fourth capacitor connected between the second differential input node and the first output node;
an adaptive reference voltage circuit to generate the adaptive reference voltage on a second reference voltage node;
a fifth switch connected between the second reference voltage node and the second output node; and
a sixth switch connected between the second reference voltage node and the first output node.

7. The amplifier circuit of claim 6, wherein the adaptive reference voltage circuit comprises a diode-connected MOS transistor connected to the second reference voltage node.

8. The amplifier circuit of claim 6,
wherein during the first potion of the input common-mode adaptation phase, the fifth and sixth switches are activated to connect the second reference voltage node to the first and second output nodes of the input common-mode voltage adaptation circuit and apply the adaptive reference voltage to both the first and second differential input terminals of the differential amplifier stage, and the first and second switches are activated to connect the first and second feedback nodes to the first reference voltage node, and pre-charge the first and second capacitors to a voltage equal to the common-mode reference voltage less the adaptive reference voltage;
wherein during the second portion of the input common-mode adaptation phase, the first, second, fifth and sixth switches are deactivated, and the third and fourth switches are activated to capacitively couple the first differential output terminal to the first differential input terminal of the differential amplifier stage via the second capacitor, and to capacitively couple the second differential output terminal to the second differential input terminal of the differential amplifier stage via the first capacitor, and
wherein during a normal operating period of the amplifier circuit following the input common-mode adaption phase, the first, second, third, fourth, fifth and sixth switches are deactivated, and the first and second input nodes of the amplifier circuit are capacitively coupled to the second and first differential input terminals of the differential amplifier stage via the third and fourth capacitors, respectively.

9. The amplifier circuit of claim 5, wherein the input common-mode voltage adaption circuit comprises:
a first reference voltage node that receives a common-mode reference voltage;
a first switch connected between the first reference voltage node and the first feedback node;
a second switch connected between the first reference voltage node and the second feedback node;
a third switch connected between the first feedback node and the second differential output terminal;
a fourth switch connected between the second feedback node and the first differential output terminal;
a first capacitor connected between the first feedback node and the second output node;
a second capacitor connected between the second feedback node and the first output node;
a third capacitor connected between the first differential input node and the first feedback node;
a fourth capacitor connected between the second differential input node and the second feedback node;
an adaptive reference voltage circuit to generate the adaptive reference voltage on a second reference voltage node;
a fifth switch connected between the second reference voltage node and the second output node; and
a sixth switch connected between the second reference voltage node and the first output node.

10. The amplifier circuit of claim 9, wherein the adaptive reference voltage circuit comprises a diode-connected MOS transistor connected to the second reference voltage node.

11. The amplifier circuit of claim 9,
wherein during the first portion of the input common-mode adaptation phase, the fifth and sixth switches are activated to connect the second reference voltage node to the first and second output nodes of the input common-mode voltage adaptation circuit and apply the adaptive reference voltage to both the first and second differential input terminals of the differential amplifier stage, and the first and second switches are activated to connect the first and second feedback nodes to the first reference voltage node, and pre-charge the first and second capacitors to a voltage equal to the common-mode reference voltage less the adaptive reference voltage;
wherein during the second portion of the input common-mode adaptation phase, the first, second, fifth and sixth switches are deactivated, and the third and fourth switches are activated to capacitively couple the first differential output terminal to the first differential input terminal of the differential amplifier stage via the second capacitor, and to capacitively couple the second differential output terminal to the second differential input terminal of the differential amplifier stage via the first capacitor, and
wherein during a normal operating period of the amplifier circuit following the adaption phase, the first, second, third, fourth, fifth and sixth switches are deactivated, and the first input node of the amplifier circuit is capacitively coupled to the second differential input terminal of the differential amplifier stage via the first and third capacitors, and the second input node of the amplifier circuit is capacitively coupled to the first differential input terminal of the differential amplifier stage via the second and fourth capacitors.

12. The amplifier circuit of claim 5, further comprising an output common-mode feedback control circuit connected to the first and second differential output terminals of the differential amplifier stage, wherein the output common-mode feedback control circuit maintains an output common-mode voltage of the first and second differential output terminals of the differential amplifier stage at a common-mode reference voltage.

13. The amplifier circuit of claim 12, wherein the output common-mode feedback control circuit comprises:
first and, second input nodes connected to the first and second differential output terminals of the differential amplifier stage;
a reference voltage node that receives the common-mode reference voltage, and
an output node connected to a gate terminal of a tail transistor of the differential amplifier stage,
wherein during a control phase, the output common-mode feedback control circuit is configured to (i) connect the first and second differential output terminals of the differential amplifier stage to the gate terminal of the tail transistor to temporarily configure the tail transistor as a diode-connected transistor, wherein a voltage on the gate terminal of the tail device is adjusted to be equal to a diode voltage of the tail transistor, and to (ii) pre-charge a first and second capacitor to a voltage equal to the common-mode reference voltage less the diode voltage.

14. A system-on-chip comprising the amplifier circuit of claim 5.

15. The system-on-chip of claim 14, wherein the system-on-chip controls a storage system for storing data to and from a storage medium.

16. An amplifier circuit, comprising:
a differential amplifier comprising a differential transistor pair and a tail transistor connected to the differential transistor pair, the differential transistor pair comprising first and second differential input terminals and first and second differential output terminals; and
an output common-mode feedback control circuit comprising:
first and second input nodes connected to the first and second differential output terminals of the differential transistor pair,
a reference voltage node that receives a common-mode reference voltage, and
an output node connected to a gate terminal of the tail transistor of the differential amplifier,
wherein the output common-mode feedback control circuit maintains an output common-mode voltage of the first and second differential output terminals of the differential amplifier at a level of the common-mode reference voltage,
wherein during a control phase, the output common-mode feedback control circuit is configured to (i) connect the first and second differential output terminals of the differential amplifier stage to the gate terminal of the tail transistor to temporarily configure the tail transistor as a diode-connected transistor, wherein a voltage on the gate terminal of the tail device is adjusted to be equal to a diode voltage of the tail transistor, and to (ii) pre-charge a first and second capacitor to a voltage equal to the common-mode reference voltage less the diode voltage.

17. The amplifier circuit of claim 16, wherein the output common-mode feedback control circuit comprises:
a first switch connected between the reference voltage node and a first feedback node;
a second switch connected between the reference voltage node and a second feedback node;
a third switch connected between the first feedback node and the first differential output terminal;
a fourth switch connected between the second feedback node and the second differential output terminal;
a fifth switch connected between the first differential output terminal and the output node of the output common-mode feedback control circuit; and
a fifth switch connected between the second differential output terminal and the output node of the output common-mode feedback control circuit,
wherein the first capacitor is connected between the first feedback node and the output node, and
wherein the second capacitor is connected between the second feedback node and the output node.

18. The amplifier circuit of claim 17,
wherein during the control phase, the fifth and sixth switches are activated by a first control signal to directly connect the first and second differential output terminals of the differential transistor pair to the gate terminal of the tail transistor, and the first and second switches are activated by the first control signal to connect the reference voltage node to the first and second capacitors to precharge the first and second capacitors; and
wherein during a normal operating period of the amplifier circuit, the first, second, fifth and sixth switches are deactivated, and the third and fourth switches are activated by a second control signal to capacitively couple the first differential output terminal of the differential transistor pair to the gate terminal of the tail transistor via the first capacitor, and to capacitively couple the second differential output terminal of the differential transistor pair to the gate terminal of the tail transistor via the second capacitor.

19. A system-on-chip comprising the amplifier circuit of claim 16.

20. The system-on-chip of claim 19, wherein the system-on-chip controls a storage system for storing data to and from a storage medium.
